(19) United States
(12) Patent Application Publication
(10) Pub. No.: US 2019/0157588 A1
(43) Pub. Date: May 23, 2019

(54) HIGH REFRACTIVE INDEX (HRI) SUBSTRATE AND METHOD FOR FABRICATION THEREOF

(71) Applicant: SABIC Global Technologies B.V., Bergen op Zoom (NL)

(72) Inventors: Sang Hoon Kim, Seoul (KR); Sang-Jin Kim, Seoul (KR)

(21) Appl. No.: 16/096,208

(22) PCT Filed: Apr. 28, 2017
(86) PCT No.: PCT/IB2017/052511

§ 371 Date: Oct. 24, 2018

Related U.S. Application Data
(60) Provisional application No. 62/329,251, filed on Apr. 29, 2016.

(51) Int. Cl. H01L 51/00; H01L 51/52; H01L 51/50; H01L 51/56

(52) U.S. Cl. CPC H01L 51/0097; H01L 51/5206; H01L 51/5036; H01L 2251/558; H01L 51/5275; H01L 2251/5369; H01L 2251/5338; H01L 51/56

(57) ABSTRACT

The disclosure concerns high refractive index substrates suitable for inclusion in an OLED, the substrate comprising a polymeric material and inorganic fine particles dispersed therein, the size of said particles ranging from about 1 nm to about 50 nm.

### TECHNICAL FIELD

The disclosure concerns multifunctional flexible substrates useful in organic light emitting diodes.

### BACKGROUND

Conventionally, in order to extract internal light from an organic light emitting diode (OLED) device, which may be trapped (e.g., internally reflected) between an indium tin oxide (ITO) layer and the substrate, certain structured layers have been developed. The low extraction efficiency of an OLED device is due at least in part to the difference in refractive index between air, the substrate, and the organic/ITO layers. Improving this low extraction efficiency remains as a challenge for lighting applications. Various techniques, which can reduce the substrate, waveguide, and surface plasmon (SR) modes in an OLED device have been researched in order to improve the extraction efficiency from the OLED device. There is a limitation to reducing the waveguide mode between the ITO layer and the substrate because the layer or structure fabricated between the ITO layer and the substrate can cause the increase of the surface roughness of ITO layer, generating high current leakage and low efficiency. In addition, such methods require a complicated fabrication process, resulting in high manufacturing cost.

These and other shortcomings are addressed by aspects of the present disclosure.

### SUMMARY

Aspects of the disclosure relate to a high refractive index (HRI) substrate which exhibits high extraction efficiency, flexibility, and high transmittance performance. The HRI substrate includes a plurality of nanoparticles dispersed in a polymeric material. The size of said particles ranges from 1 nanometer (nm) to 50 nm or from about 1 nm to about 50 nm, or from greater than 100 nm to 200 nm or from greater than 100 to about 200 nm.

In some aspects the HRI substrate may include particles having a size greater than 100 nm as scattering layer. HRI substrates including such particles may exhibit a higher extraction efficiency from an OLED device.

Some aspects concern use of high-refractive-index (HRI) substrate and its various fabrication methods for an OLED device.

In some aspects, nanoparticles (smaller than 50 nm) having a high refractive index (n) (n=1.7-2.5, or about 1.7 to about 2.5) are mixed with polymeric pellets or a polymeric solution, and then the mixture is extruded as substrate or film layer. In addition, particles, which are larger than 100 nm size, can be mixed into the HRI substrate in order to be used as scattering layer. Through this approach, we can provide the HRI substrate having high extraction efficiency, flexibility, and high transmittance performance for OLED device application and future industrial applications. The disclosure also concerns articles comprising such flexible substrates and methods of making such articles and substrates.

In yet other aspects, the disclosure concerns OLEDs comprising the HRI substrate, methods of making the HRI substrate and methods of making OLEDs comprising the HRI substrates.

### BRIEF DESCRIPTION OF THE DRAWINGS

FIG. 1 shows schematic of high refractive index substrate how it can improve light extraction.

FIG. 2 presents a schematic of example of the structure per refractive index gradation.

FIG. 3 shows a process schematic for the substrate with the gradation of refractive index made by atomic layer deposition.

FIG. 4 presents a schematic of how to fabricate HRI film by using screen printing method.

FIG. 5 presents shows the process schematic of how to produce by the injection process. The nanoparticle compounding ratio ranges from 90 wt. % to 5%.

FIG. 6 shows the structure of transparent electrode on HRI substrate of which RI ranges from 1.7 to 2.0.

FIG. 7 shows the illustration of the example of transparent electrode formation on HRI substrate. Metal oxide such as indium tin oxide (ITO), tin (II) oxide (SnO), indium gallium zinc oxide (IGZO), indium zinc oxide (IZO) can be deposited onto high heat resistant with high refractive index substrate. Or metal oxide such as liquid solution of ITO, SnO, IGZO, IZO can be coated and cured by intense pulse light sintering method. In this case, ULTEM™ was used for base substrate.

FIGS. 8A and 8B presents a schematic of high refractive index substrate integrated with a transparent electrode layer.

### DETAILED DESCRIPTION OF ILLUSTRATIVE EMBODIMENTS

In some aspects, fabricating the high refractive index (HRI) substrate, nano-particles are contained within a polymeric substrate. The nanoparticles (with high refractive index (n=1.7-2.5)) are dispersed into the polymeric pellets or a polymeric solution or silicone solution. This mixture can then be used to fabricate the substrate using conventional technology.

The HRI substrate, which can reduce the waveguide mode from OLED device, can exhibit high extraction efficiency and flexibility compared to the conventional glass substrate, when it is applied to OLED device. As a different example, by adding the particle with larger size than 100 nm as scattering layer, this HRI substrate can exhibit higher extraction efficiency from OLED device. As a result, we can accomplish higher efficiency and flexible OLED by using the HRI substrate with a scattering layer. Additionally, the HRI substrate can satisfy the various requirements such as low cost, thin thickness, and high efficiency, replacing rigid substrate like glass.

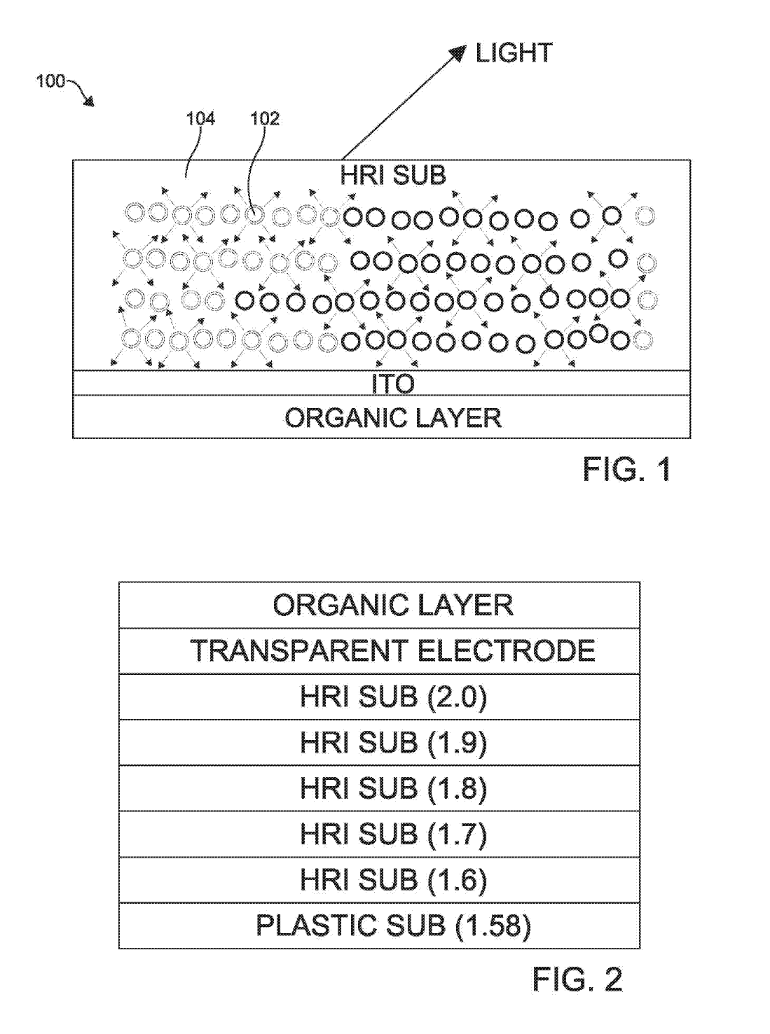

FIG. 1 shows a schematic of high refractive index substrate 100 and how the substrate can improve light extraction. Nanoparticles 102 having a high refractive index are dispersed in a polymer solution 104, and then this layer can be formed as a film.

### HRI Substrate

The HRI substrate may contain a base substrate that includes a polymeric material having transparency. Suitable polymeric materials include polycarbonate (PC), polyethylene terephthalate (PET), polyethylene naphthalate (PEN), polybutylene terephthalate (PBT), polyester, polyether sulfone (PES), polyether ether ketone (PEEK) and combinations thereof. In some aspects the base substrate includes PEN or PET. In further aspects the base substrate includes polycarbonate. In certain aspects the base substrate has one or more of the properties selected from surface roughness, transparency and chemical resistance. In some aspects PEN demonstrates these properties when included in the base substrate. The initial thickness for the base substrate may be 100 micrometers (microns, μm) to 150 μm (or about 100 μm to about 150 μm) for handling purposes. While a thin film is desired in some aspects, a film that is too thin can be difficult to control. Regardless of the properties in base substrate, coated materials can provide a high performance barrier. Therefore, machinery for the process to optimize the density of coated material may be used. The thickness of the coating layer may be 100 nm to 150 nm or from about 100 nm to about 150 nm.

In certain aspects the substrate is flexible and has nanoparticles dispersed therein, the size of said particles ranging from 5 μm to 250 μm or about 5 μm to about 250 μm. In some aspects, the substrate has a refractive index (n) of from 1.7 to 2.5 or from about 1.7 to about 2.5. In particular aspects the substrates have a transmittance from 80% to 95% or about 80% to about 95%. In further aspects the substrates have a water vapor transmission rate (WVTR) of 10⁻⁶ grams per square meter per day (g/m²day). The substrates including the dispersed inorganic fine particles may exhibit improved storage modulus and reduced efficiency of thermal expansion as compared to a substantially similar substrate without the inorganic fine particles. Substantially similar may mean the same materials and structure prepared under the same conditions within tolerance.

Additionally, preferred substrates have no photocatalytic reactivity in the ultraviolet (UV) wavelength range and have a yellow index value below 2.

As shown in FIG. 2, a plurality of HRI substrates may reside on a polymeric support substrate. In some aspects, the HRI substrates will vary in refractive index. In a particular aspect the support substrate has a refractive index of 1.58 (polymeric substrate) and the HRI substrate layers each have a larger refractive index as they reside more remote from the support substrate. The polymeric support substrate may optionally be free of inorganic nanoparticles and constructed from the polymers discussed above for the HRI substrates.

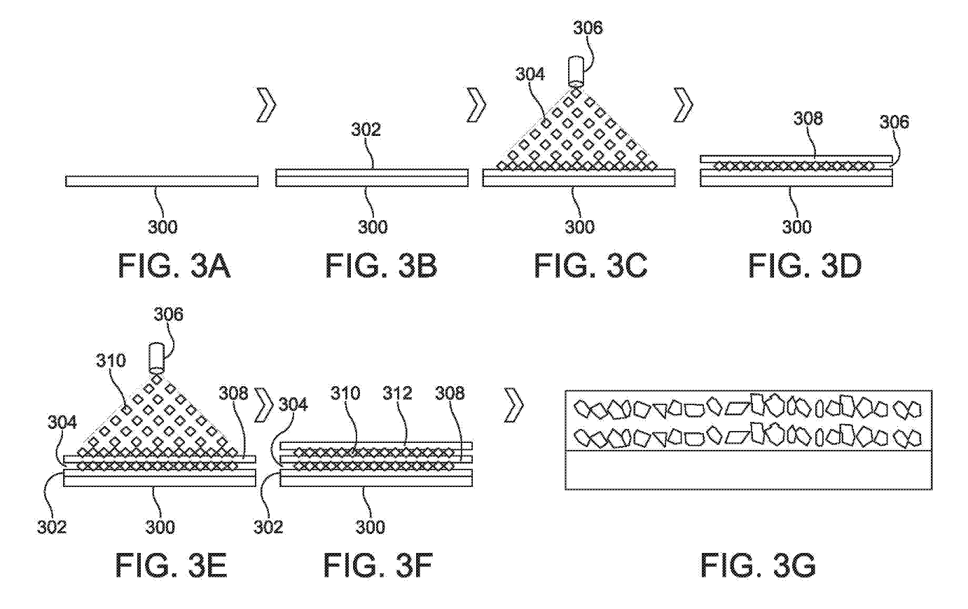

FIG. 3 illustrates forming a HRI substrate with the gradation of refractive index, which can be made by atomic layer deposition or slot die coating. FIG. 3A presents the substrate, or polymer film, to which a first coating adhesive 302 is added in FIG. 3B. At FIG. 3C, a first plurality of nanoparticles 304 are applied to the first coating adhesive 302 via a sprayer 306 for example. A second coating adhesive 308 may be applied as shown in FIG. 3D. A second plurality of nanoparticles 310 may be applied to the second coating adhesive 308 as shown in FIG. 3E. In FIG. 3F, a third adhesive coating 312 may be applied thereby forming the nanoparticle multilayers presented in FIG. 3G. Each layer has thickness ranges from 5 nm to 100 nm, or from about 5 nm to about 100 nm. The refractive index can be adjusted by varying the thickness of each layer. In a further example, each layer (i.e., the first or second, or subsequent pluralities of nanoparticles) can be different nanoparticles each having a respective refractive index.

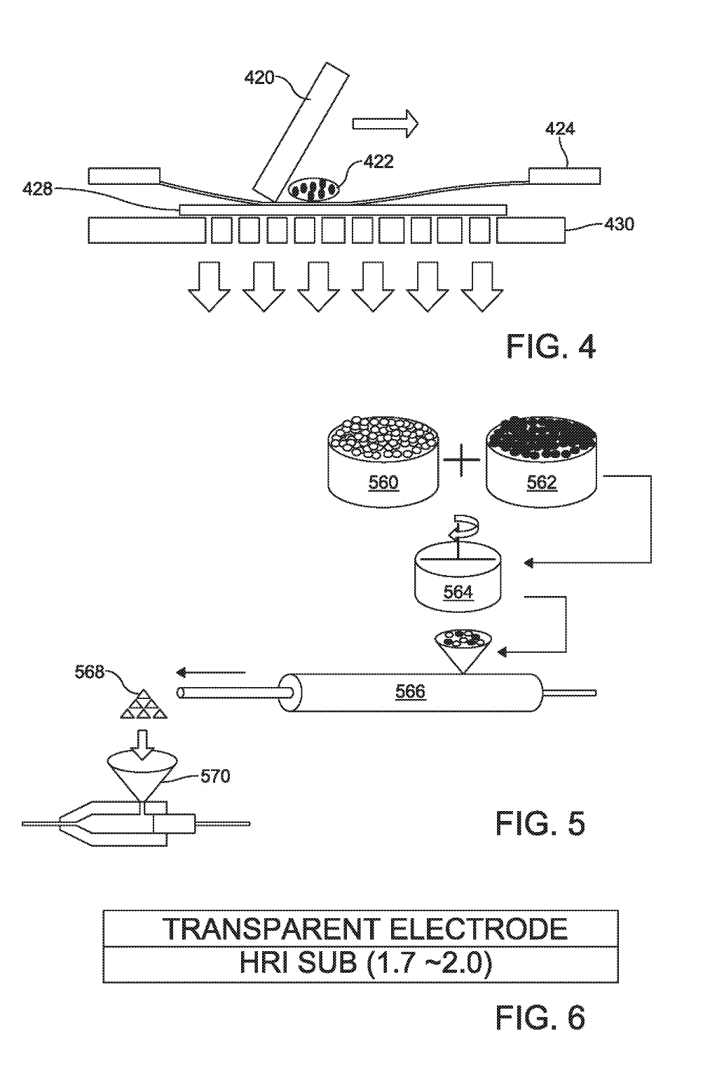

FIG. 4 shows the schematic of how to fabricate HRI film via an exemplary, but not to be limiting, screen printing method. A squeegee 420 or other spreading device may be used to dispose a nanoparticle solution 422 across a mesh 424 (held in place by a frame) 426, where the mesh is disposed adjacent a surface of a polymer substrate 428. The substrate is held in position at a support, such as a table 430, equipped with vacuum pressure.

FIG. 5 shows one process schematic of how to produce a HRI layer by the injection process. Polymer 560 and a nanoparticle dispersion solution 562 may be combined in a vessel 564. The combination may be compounded and pelletized in an extruder 566 to form pellets 568 and then injected molded in an injection molding apparatus 570 to provide a film or layer. The nanoparticle compounding ratio ranges from 5 wt. % to 90 wt. % in some aspects.

In certain aspects the substrate is highly durable and has chemical resistance to acids, bases and/or organic solvents.

### Nanoparticles

The particles used in the HRI substrate layer typically range from 5 μm to 250 μm or from about 5 μm to about 250 μm. Some preferred particles have a diameter of less than 50 nm.

Exemplary particles in some aspects include nanoparticles comprising one or more of Zirconium oxide (ZrO₂), Zinc oxide (ZnO), Aluminum oxide (Al₂O₃), Magnesium oxide (MgO), Calcium oxide (CaO), Aluminum nitride (AlN), Barium titanate (BaTiO₃), Hafnium oxide (HfO₂), Tantalum oxide (Ta₂O₅), Cerium oxide (CeO₂), Yttrium oxide (Y₂O₃), Titanium oxide (TiO₂), Indium Gallium Zinc oxide (IGZO), Indium doped Zinc oxide (IZO), and Tin oxide (SnO). In addition, stabilized or partially stabilized zirconia (e.g., Y₂O₃—ZrO₂, MgO—ZrO₂, CaO—ZrO₂, CeO₂—ZrO₂, Al₂O₃) may be used as nanoparticles in certain aspects. Further, the nanoparticles may be in a solution (or dispersed throughout a solution) including one or more of the above nanoparticles.

### Barrier Layer

An optional barrier layer may include one or both of inorganic and organic materials. For example, the barrier layer may comprise inorganic particles in a polymer media. The layer may comprise a metal oxide such as oxides of aluminum, zirconium, zinc, titanium, and silicone (such as Al₂O₃, ZrO₂, ZnO, TiO₂, TiOₓ, SiO₂, and SiOₓ), and a polymer comprising acrylate-polymer, parylene, p-xylene, or ethylene glycol. Polymer layers may be formed by molecular layer deposition (e.g., by molecular layer deposition of ethylene-glycol), plasma polymer (e.g., direct radical polymerization by plasma) or other applications known to those skilled in the art. In some aspects the barrier layer has a thickness of from 0.5 μm to 50 μm, or from about 0.5 μm to about 50 μm.

### Electrode Layer

In some aspects the electrode layer is transparent and is constructed from materials such as, but not limited to, ITO, SnO₂, ZnO, iridium zinc oxide, ZnO—Al₂O₃ (a zinc oxide doped with aluminum), ZnO₄Ga₂O₃ (a zinc oxide doped with gallium), niobium Nb-doped TiO₂, Ta-doped TiO₂, metals such as gold Au and platinum Pt, and combinations thereof In certain aspects the layer has a thickness of 50 μm to 50 nm or from about 50 nm to about 1 μm, or a thickness of 100 nm to 1 μm or from about 100 nm to about 1 μm.

Indium tin oxide (ITO) may be used as the anode material in certain aspects. Metals such as barium and calcium may be used for the cathode material in further aspects.

FIG. 6 shows the structure of transparent electrode on HRI substrate of which the refractive index ranges from 1.7 to 2.0, or from about 1.7 to about 2.0.

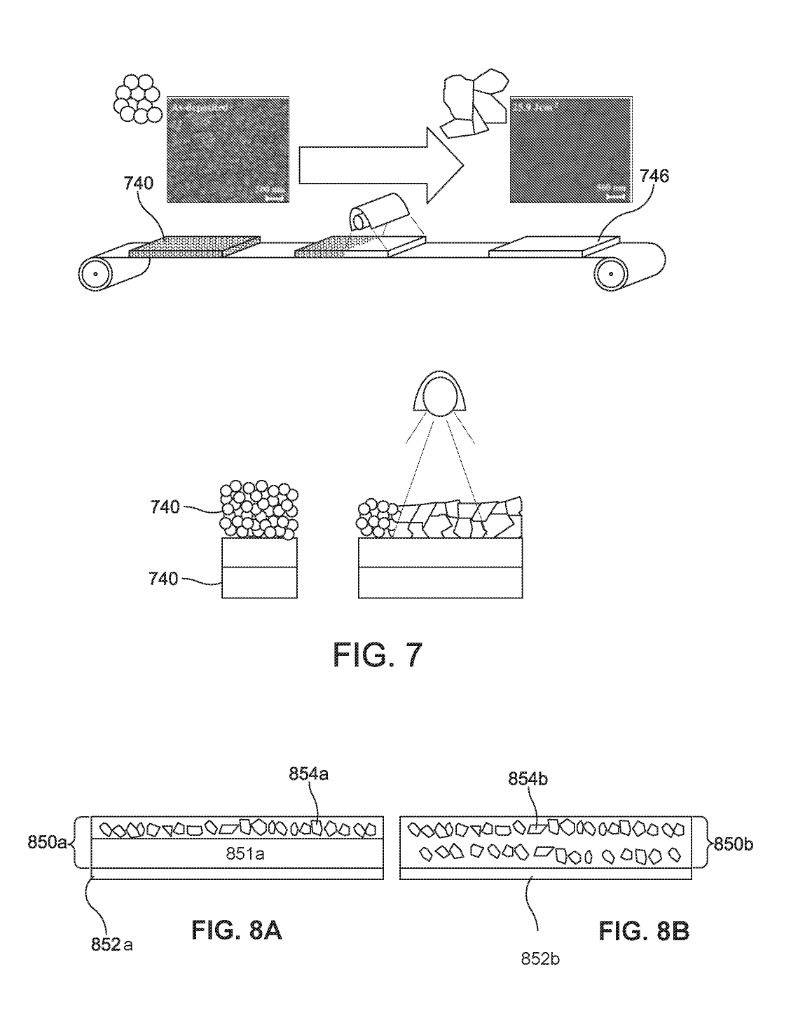

FIG. 7 shows an illustration of transparent electrode formation on a HRI substrate. Metal oxide such as ITO, SnO, IGZO, IZO can be deposited onto high heat resistant substrate having a high refractive index substrate. Alternatively, a liquid solution of metal oxide (e.g., ITO, SnO, IGZO, IZO) can be coated and cured by a pulse light sintering method in some aspects. In a particular aspect, ULTEM™, an amorphous polyetherimide resin commercially available from SABIC™, may be used for base substrate. Nanoparticles 740 may coat the ULTEM™ substrate 742. Curing by a heat source 744, for example, is subsequently applied forming the bulk film (transparent electrode) 746.

### Phosphor Layer

The phosphor layer (or organic layer) may comprise a phosphorescent dopant in a polymer that is transparent when the layer is formed. Different phosphorescent dopants are known in the art and can be selected based on desired color output and other properties. Such dopants include, but are not limited to, the use of YAG:Ce phosphors for yellow and CASN:Eu phosphors for red. YAG is yttrium aluminum garnet (Y₃Al₅O₁₂). YAG:Ce is cerium-doped YAG (YAG:Ce). CASN is CaAlSiN₃ and CASN:Eu is europium-doped CASN.

Silicones such as polydimethylsiloxane (PDMS) or acrylic or urethane based material could be used as binder material.

### Polymers

Various polymers disclosed herein are available from commercial sources.

### Polycarbonate

One preferred polymer useful in forming flexible substrates is polycarbonate. The terms “polycarbonate” or “polycarbonates” as used herein include copolycarbonates, homopolycarbonates and (co)polyester carbonates.

The term polycarbonate can be further defined as compositions have repeating structural units of the formula (1):

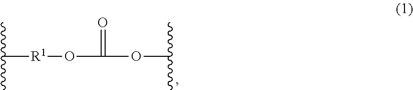

in which at least 60 percent of the total number of R¹ groups are aromatic organic radicals and the balance thereof are aliphatic, alicyclic, or aromatic radicals. In a further aspect, each R¹ is an aromatic organic radical and, more preferably, a radical of the formula (2):

-A1-Y1-A2- (2),

wherein each of A1 and A2 is a monocyclic divalent aryl radical and Y1 is a bridging radical having one or two atoms that separate A1 from A2. In various aspects, one atom separates A1 from A2. For example, radicals of this type include, but are not limited to, radicals such as —O—, —S—, —S(O)—, —S(O₂)—, —C(O)—, methylene, cyclohexyl-methylene, 2-[2.2.1]-bicycloheptylidene, ethylidene, isopropylidene, neopentylidene, cyclohexylidene, cyclopentadecylidene, cyclododecylidene, and adamantylidene. The bridging radical Y1 is preferably a hydrocarbon group or a saturated hydrocarbon group such as methylene, cyclohexylidene, or isopropylidene. Polycarbonate materials include materials disclosed and described in U.S. Pat. No. 7,786,246, which is hereby incorporated by reference in its entirety for the specific purpose of disclosing various polycarbonate compositions and methods for manufacture of the same.

A melt polycarbonate product may be utilized in the instant structures and methods. The melt polycarbonate process is based on continuous reaction of a dihydroxy compound and a carbonate source in a molten stage. The reaction can occur in a series of reactors where the combined effect of catalyst, temperature, vacuum, and agitation allows for monomer reaction and removal of reaction by-products to displace the reaction equilibrium and effect polymer chain growth. A common polycarbonate made in melt polymerization reactions is derived from bisphenol A (BPA) via reaction with diphenyl carbonate (DPC). This reaction can be catalyzed by, for example, tetra methyl ammonium hydroxide (TMAOH) or tetrabutyl phosphonium acetate (TBPA), which can be added in to a monomer mixture prior to being introduced to a first polymerization unit and sodium hydroxide (NaOH), which can be added to the first reactor or upstream of the first reactor and after a monomer mixer.

### Polyetherimides

Another useful polymer for forming substrates is polyetherimide. As disclosed herein, the composition can comprise polyetherimides. Polyetherimides includes polyetherimide copolymers. The polyetherimide can be selected from (i) polyetherimide homopolymers, e.g., polyetherimides, (ii) polyetherimide co-polymers, e.g., polyetherimidesulfones, and (iii) combinations thereof. Polyetherimides are known polymers and are sold by SABIC Innovative Plastics under the ULTEM™, EXTEM™, and SILTEM™ brands.

In an aspect, the polyetherimides can be of formula (3):

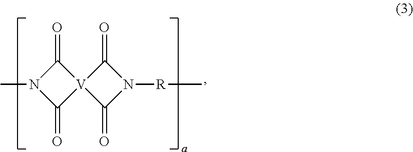

wherein a is more than 1, for example 10 to 1,000 or more, or more specifically 10 to 500. In one example, a can be 10-100, 10-75, 10-50 or 10-25.

The group V in formula (3) is a tetravalent linker containing an ether group (a “polyetherimide” as used herein) or a combination of an ether groups and arylenesulfone groups (a “polyetherimidesulfone”). Such linkers include but are not limited to: (a) substituted or unsubstituted, saturated, unsaturated or aromatic monocyclic and polycyclic groups having 5 to 50 carbon atoms, optionally substituted with ether groups, arylenesulfone groups, or a combination of ether groups and arylenesulfone groups; and (b) substituted or unsubstituted, linear or branched, saturated or unsaturated alkyl groups having 1 to 30 carbon atoms and optionally substituted with ether groups or a combination of ether groups, arylenesulfone groups, and arylenesulfone groups; or combinations comprising at least one of the foregoing. Suitable additional substitutions include, but are not limited to, ethers, amides, esters, and combinations comprising at least one of the foregoing.

The R group in formula (3) includes but is not limited to substituted or unsubstituted divalent organic groups such as: (a) aromatic hydrocarbon groups having 6 to 20 carbon atoms and halogenated derivatives thereof; (b) straight or branched chain alkylene groups having 2 to 20 carbon atoms; (c) cycloalkylene groups having 3 to 20 carbon atoms, or (d) divalent groups of formula (4):

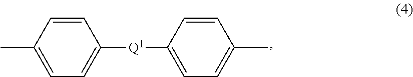

wherein Q1 includes but is not limited to a divalent moiety such as —O—, —S—, —C(O)—, —SO₂—, —SO—, —CyH₂y- (y being an integer from 1 to 5), and halogenated derivatives thereof, including perfluoroalkylene groups.

The disclosure also utilizes the polyimides disclosed in U.S. Pat. No. 8,784,719 which is incorporated herein in its entirety. In addition, the polyetherimide resin can be selected from the group consisting of a polyetherimide, for example as described in U.S. Pat. Nos. 3,875,116; 6,919,422 and 6,355,723, a silicone polyetherimide, for example as described in U.S. Pat. Nos. 4,690,997; 4,808,686, a polyetherimidesulfone resin, as described in U.S. Pat. No. 7,041,773, and combinations thereof, each of these patents are incorporated herein by their entirety.

The polyetherimides can have a weight average molecular weight (Mw) of 5,000 to 100,000 grams per mole (g/mole) as measured by gel permeation chromatography (GPC). In some aspects the Mw can be 10,000 to 80,000. The molecular weights as used herein refer to the absolute weight average molecular weight (Mw).

### Other Polymers

Other polymers discussed herein are available from commercial sources or can be made by methods known to those skilled in the art.

### Formation of OLED Layers

Various layers of an OLED may be formed by use of one or more of ink jet printing, application of a polymer solution or slurry, roll to roll printing, vacuum vapor deposition operations or other techniques known to those skilled in the art. Additionally, aerosol-deposition process can be used for phosphor layer coating.

In certain aspects, one or more of the layers may be laminated. The disclosure contemplates all combinations of laminated and non-laminated assembly of each layer into a single sheet.

### Definitions

It is to be understood that the terminology used herein is for the purpose of describing particular aspects only and is not intended to be limiting. As used in the specification and in the claims, the term “comprising” can include the embodiments “consisting of” and “consisting essentially of” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “transparent” means that the level of transmittance for a disclosed composition is greater than 50%. It is preferred that the transmittance be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

The terms “refractive index” or “index of refraction” as used herein refer to a dimensionless number that is a measure of the speed of light in that substance or medium. It is typically expressed as a ratio of the speed of light in vacuum relative to that in the considered substance or medium. This can be written mathematically as:

n=speed of light in a vacuum/speed of light in medium.

The term “adhesive” as used herein refers to a sticky, gluey or tacky substance capable of adhering two films together. It is preferred that the adhesive be transparent. In the adhesive, desiccant material can be added for improving WVTR property. And UV or thermal energy may be necessary for curing adhesive layer.

“UV” stands for ultraviolet.

The abbreviation “nm” stands for nanometer(s).

The abbreviation “μm” stands for micrometer(s).

As used herein the terms “weight percent,” “wt. %,” and “wt. %” of a component, which can be used interchangeably, unless specifically stated to the contrary, are based on the total weight of the formulation or composition in which the component is included. For example if a particular element or component in a composition or article is said to have 8% by weight, it is understood that this percentage is relative to a total compositional percentage of 100% by weight.

As used herein, the terms “weight average molecular weight” or “Mw” can be used interchangeably, and are defined by the formula:

$${M}_{w} = \frac{\sum {N}_{i} {M}_{i}^{2}}{\sum {N}_{i} {M}_{i}} ,$$

where Mᵢ is the molecular weight of a chain and Nᵢ is the number of chains of that molecular weight. Compared to Mₙ, M_{w} takes into account the molecular weight of a given chain in determining contributions to the molecular weight average. Thus, the greater the molecular weight of a given chain, the more the chain contributes to the M_{w}. M_{w} can be determined for polymers, e.g. polycarbonate polymers, by methods well known to a person having ordinary skill in the art using molecular weight standards, e.g. polycarbonate standards or polystyrene standards, preferably certified or traceable molecular weight standards.

Water vapor transmission rate (WVTR) may be determined by any suitable method, including but not limited to a tritium test and a Ca test. Mocon, of Minneapolis, Minn., provides equipment for measuring WVTR of thin films such as those described herein.

Yellow index can be determined by ASTM E313.

Unless otherwise stated to the contrary herein, all test standards are the most recent standard in effect at the time of filing this application.

### Aspects

The present disclosure comprises at least the following aspects.

Aspect 1. A high refractive index substrate suitable for inclusion in an OLED, said substrate comprising a polymeric material and inorganic fine particles dispersed therein, the size of first inorganic fine particles ranging from about 1 nm to about 50 nm or from greater than 100 nm to about 200 nm.

Aspect 2. A high refractive index substrate suitable for inclusion in an OLED, said substrate consisting essentially of a polymeric material and inorganic fine particles dispersed therein, the size of said particles ranging from about 1 nm to about 50 nm.

Aspect 3. A high refractive index substrate suitable for inclusion in an OLED, said substrate consisting of a polymeric material and inorganic fine particles dispersed therein, the size of the inorganic fine particles ranging from about 1 nm to about 50 nm or from greater than 100 nm to about 200 nm.

Aspect 4. A high refractive index substrate suitable for inclusion in an OLED, said substrate comprising a polymeric material and inorganic fine particles dispersed therein, the size of the inorganic fine particles ranging from 1 nm to 50 nm or from greater than 100 nm to about 200 nm.

Aspect 5. The high refractive index substrate according to any of Aspects 1-4, wherein the high refractive index substrate is flexible and has a thickness in the range of from about 5 μm to about 250 μm.

Aspect 6. The high refractive index substrate according to any of Aspects 1-5, having a refractive index (n) of from about 1.7 to about 2.5.

Aspect 7. The high refractive index substrate according to any of Aspects 1-5, having a refractive index (n) of from 1.7 to 2.5.

Aspect 8. The high refractive index substrate according to any of Aspects 1-7, having a transmittance greater than 80%.

Aspect 9. The high refractive index substrate according to any of Aspects 1-7, having a transmittance greater than 90%.

Aspect 10. The high refractive index substrate according to any of Aspects 1-7, having a transmittance from about 80% to about 95%.

Aspect 11. The high refractive index substrate according to any of Aspects 1-10, having a water vapor transmission rate (WVTR) of about 10⁻⁶ g/m²day.

Aspect 12. The high refractive index substrate according to any of Aspects 1-10, having a water vapor transmission rate (WVTR) of about 10⁻⁶ g/m²day.

Aspect 13. The high refractive index substrate according to any of Aspects 1-12, wherein said nanoparticles have a particle diameter less than 50 nm.

Aspect 14. The high refractive index substrate according to any of Aspects 1-13, wherein the polymeric material comprises polycarbonate or polyetherimide.

Aspect 15. The high refractive index substrate according to any of Aspects 1-14, wherein the inorganic fine particles comprise one or more of Zirconium oxide (ZrO₂), Zinc oxide (ZnO), Aluminum oxide (Al₂O₃), Magnesium oxide (MgO), Calcium oxide (CaO), Aluminum nitride (AlN), Barium titanate (BaTiO₃), Hafnium oxide (HfO₂), Tantalum oxide (Ta₂O₅), Cerium oxide (CeO₂), Yttrium oxide (Y₂O₃), Titanium oxide (TiO₂), Indium Gallium Zinc oxide (IGZO), Indium doped Zinc oxide (IZO), Tin oxide (SnO), and stabilized or partially stabilized zirconia.

Aspect 16. The high refractive index substrate according to any of Aspects 1-15, where the substrate has a heat resistance of from 120° C. to 250° C.

Aspect 17. The high refractive index substrate according to any of Aspects 1-16, wherein the substrate has no photocatalytic reactivity in ultraviolet (UV) wavelength range.

Aspect 18. The high refractive index substrate according to any of Aspects 1-17, wherein the substrate has no photocatalytic reactivity in the 10 nm to 400 nm wavelength range.

Aspect 19. The high refractive index substrate according to any of Aspects 1-18, where the substrate has a yellow index value below 2.

Aspect 20. The high refractive index substrate according to any of Aspects 1-19, comprising a plurality of high refractive index substrate layers, wherein the layers are formed atomic layer deposition coatings or slot die coatings.

Aspect 21. The high refractive index substrate according to any of Aspects 1-20, additionally comprising a transparent electrode layer.

Aspect 22. The high refractive index substrate according to any of Aspects 1-21, wherein gradation of refractive index is achieved by depositing the inorganic fine particles onto the adhesive coated substrate via a sprayer or spraying means.

Aspect 23. The high refractive index substrate according to any of Aspects 1-22, wherein the inorganic fine particles having a size ranging from about 100 nm to about 30 μm are formed by an adhesive transfer method, coating method or a deposition method.

Aspect 24. An OLED comprising an anode; a phosphor layer; a high refractive index substrate according to any of Aspects 1-15; an anode layer, said anode disposed adjacent to said substrate; a phosphor layer disposed on the anode layer; and a cathode layer disposed on said phosphor layer.

Aspect 25. An OLED consisting essentially of an anode; a phosphor layer; a high refractive index substrate according to any of Aspects 1-15; an anode layer, said anode disposed adjacent to said substrate; a phosphor layer disposed on the anode layer; and a cathode layer disposed on said phosphor layer.

Aspect 26. An OLED consisting of an anode; a phosphor layer; a high refractive index substrate according to any of Aspects 1-15; an anode layer, said anode disposed adjacent to said substrate; a phosphor layer disposed on the anode layer; and a cathode layer disposed on said phosphor layer.

Aspect 27. The OLED of Aspect 16, wherein the high refractive index substrate is flexible and has a thickness in the range of from about 5 μm to about 250 μm.

Aspect 28. The OLED of Aspect 16, wherein the high refractive index substrate is flexible and has a thickness in the range of from 5 μm to 250 μm.

Aspect 29. The OLED of Aspect 16 or Aspect 17, wherein the high refractive index substrate having a refractive index (n) of from about 1.7 to about 2.5.

Aspect 30. The OLED of Aspect 16 or Aspect 17, wherein the high refractive index substrate having a refractive index (n) of from 1.7 to 2.5.

Aspect 31. The OLED according to any of Aspects 16-18, wherein the high refractive index substrate has a transmittance of greater than 80%.

Aspect 32. The OLED according to any of Aspects 16-18, wherein the high refractive index substrate has of greater than 85%.

Aspect 33. The OLED according to any of Aspects 16-18, wherein the high refractive index substrate has of from greater than 90% to 95%.

Aspect 34. The OLED according to any of Aspects 16-18, wherein the high refractive index substrate has a transmittance from about 80% to about 95%.

Aspect 35. The OLED according to any of Aspects 16-18, wherein the high refractive index substrate has a transmittance from 80% to 95%.

Aspect 36. The OLED according to any of Aspects 16-19, wherein the high refractive index substrate has a water vapor transmission rate (WVTR) of about 10⁻⁶ g/m²day.

Aspect 37. The OLED according to any of Aspects 16-19, wherein the high refractive index substrate has a water vapor transmission rate (WVTR) of 10⁻⁶ g/m²day.

Aspect 38. The OLED according to any of Aspects 16-20, wherein the high refractive index comprises inorganic fine particles, the inorganic fine particles comprising one or more of Zirconium oxide (ZrO₂), Zinc oxide (ZnO), Aluminum oxide (Al₂O₃), Magnesium oxide (MgO), Calcium oxide (CaO), Aluminum nitride (AlN), Barium titanate (BaTiO₃), Hafnium oxide (HfO₂), Tantalum oxide (Ta₂O₅), Cerium oxide (CeO₂), Yttrium oxide (Y₂O₃), Titanium oxide (TiO₂), Indium Gallium Zinc oxide (IGZO), Indium doped Zinc oxide (IZO), Tin oxide (SnO), and stabilized or partially stabilized zirconia.

Aspect 39. The OLED according to any of Aspects 16-21, wherein the high refractive index substrate has a heat resistance of from about 120° C. to about 250° C.

Aspect 40. The OLED according to any of Aspects 16-21, wherein the high refractive index substrate has a heat resistance of from 120° C. to 250° C.

Aspect 41. A substrate suitable for inclusion in an OLED, the substrate comprising a polymeric material and nanoparticles dispersed therein, the size of the nanoparticles ranging from greater than 100 nm to about 200 nm.

Aspect 42. A high refractive index substrate suitable for inclusion in an OLED, the high refractive index substrate comprising a polymeric material and nanoparticles dispersed therein, the size of the nanoparticles ranging from greater than 100 nm to about 200 nm.

Aspect 43. A high refractive index substrate suitable for inclusion in an OLED, the high refractive index substrate consisting essentially of a polymeric material and nanoparticles dispersed therein, the size of the nanoparticles ranging from greater than 100 nm to about 200 nm.

Aspect 44. A high refractive index substrate suitable for inclusion in an OLED, the high refractive index substrate consisting of a polymeric material and nanoparticles dispersed therein, the size of the nanoparticles ranging from greater than 100 nm to about 200 nm.

Aspect 45. A high refractive index substrate suitable for inclusion in an OLED, the high refractive index substrate comprising a polymeric material and nanoparticles dispersed therein, the size of the nanoparticles ranging from greater than 100 nm to about 200 nm.

Aspect 46. A high refractive index substrate suitable for inclusion in an OLED, the high refractive index substrate comprising a polymeric material and nanoparticles dispersed therein, the size of the nanoparticles ranging from about 1 nm to about 50 nm.

Aspect 47. The high refractive index substrate according to any of Aspects 1-2, wherein the high refractive index substrate is flexible and has a thickness in the range of from about 5 μm to about 250 μm.

Aspect 48. The high refractive index substrate according to any of Aspects 1-3, having a refractive index (n) of from about 1.7 to about 2.5.

Aspect 49. The high refractive index substrate according to any of Aspects 1-3, having a refractive index (n) of from 1.7 to 2.5.

Aspect 50. The substrate according to any of Aspects 1-3, having a transmittance greater than 80%.

Aspect 51. The substrate according to any of Aspects 1-3, having a transmittance greater than 90%.

Aspect 52. The substrate according to any of Aspects 1-3, having a transmittance from about 80% to about 95%.

Aspect 53. The high refractive index substrate according to any of Aspects 1-4, having a transmittance from 80% to 95%.

Aspect 54. The high refractive index substrate according to any of Aspects 1-5, having a water vapor transmission rate (WVTR) of 10⁻⁶ g/m2day.

Aspect 55. The high refractive index substrate according to any of Aspects 1-5, having a water vapor transmission rate (WVTR) of about 10⁻⁶ g/m2day.

Aspect 56. The high refractive index substrate according to any of Aspects 1-6, wherein said polymeric material comprises polycarbonate or polyetherimide.

Aspect 57. The high refractive index substrate according to any of Aspects 1-7, wherein said nanoparticles comprise one or more of Zirconium oxide (ZrO2), Zinc oxide (ZnO), Aluminum oxide (Al2O3), Magnesium oxide (MgO), Calcium oxide (CaO), Aluminum nitride (AlN), Barium titanate (BaTiO3), Hafnium oxide (HfO2), Tantalum oxide (Ta2O5), Cerium oxide (CeO2), Yttrium oxide (Y2O3), Titanium oxide (TiO2), Indium Gallium Zinc oxide (IGZO), Indium doped Zinc oxide (IZO), Tin oxide (SnO), and stabilized or partially stabilized zirconia.

Aspect 58. The high refractive index substrate according to any of Aspects 1-8, where the high refractive index substrate including the nanoparticles dispersed therein exhibits improved storage modulus and reduced efficiency of thermal expansion as compared to a substantially similar substrate without the nanoparticles.

Aspect 59. The high refractive index substrate according to any of Aspects 1-9, wherein said high refractive index substrate has no photocatalytic reactivity in ultraviolet wavelength range.

Aspect 60. The high refractive index substrate according to any of Aspects 1-10, where the high refractive index substrate has a yellow index value below 2.

Aspect 61. The high refractive index substrate according to any of Aspects 1-11, additionally comprising a transparent electrode layer.

Aspect 62. The high refractive index substrate according to any of Aspects 1-12, wherein a gradation of refractive index is achieved coating an adhesive on to the high refractive index substrate and by spraying the nanoparticles onto the adhesive.

Aspect 63. The high refractive index substrate according to any of Aspects 1-13, wherein the nanoparticles have a size ranging from about 100 nm to about 30 μm were formed by an adhesive transfer method, coating method or a deposition method.

Aspect 64. The high refractive index substrate according to any of Aspects 1-13, wherein the nanoparticles have a size ranging from 100 nm to 30 μm were formed by an adhesive transfer method, coating method or a deposition method.

Aspect 65. An OLED comprising an anode; a phosphor layer; a high refractive index substrate according to any of Aspects 1-2; an anode layer, said anode disposed adjacent to the high refractive index substrate; a phosphor layer disposed on the anode layer; and a cathode layer disposed on said phosphor layer.

Aspect 66. The OLED of Aspect 15, wherein the high refractive index substrate is flexible and has a thickness in the range of from about 5 μm to about 250 μm.

Aspect 67. The OLED of Aspect 15, wherein the high refractive index substrate is flexible and has a thickness in the range of from 5 μm to 250 μm.

Aspect 68. The OLED of Aspect 15 or aspect 16, wherein the high refractive index substrate having a refractive index (n) of from about 1.7 to about 2.5.

Aspect 69. The OLED of Aspect 15 or 16, wherein the high refractive index substrate having a refractive index (n) of from 1.7 to 2.5.

Aspect 70. The OLED according to any of Aspects 1-3, having a transmittance greater than 80%.

Aspect 71. The OLED according to any of Aspects 1-3, having a transmittance greater than 90%.

Aspect 72. The OLED according to any of Aspects 1-3, having a transmittance from about 80% to about 95%.

Aspect 73. The OLED according to any of Aspects 1-4, having a transmittance from 80% to 95%.

Aspect 74. The OLED according to any of Aspects 15-17, wherein the high refractive index substrate has a transmittance from about 80% to about 95%.

Aspect 75. The OLED according to any of Aspects 15-18, wherein the high refractive index substrate has a water vapor transmission rate (WVTR) of 10⁻⁶ g/m²day.

Aspect 76. The OLED according to any of Aspects 15-18, wherein the high refractive index substrate has a water vapor transmission rate (WVTR) of 10⁻⁶ g/m²day.

Aspect 77. The OLED according to any of Aspects 15-20, the high refractive index substrate comprises nanoparticles dispersed throughout, wherein the nanoparticles comprise one or more of Zirconium oxide (ZrO2), Zinc oxide (ZnO), Aluminum oxide (Al2O3), Magnesium oxide (MgO), Calcium oxide (CaO), Aluminum nitride (AlN), Barium titanate (BaTiO3), Hafnium oxide (HfO2), Tantalum oxide (Ta2O5), Cerium oxide (CeO2), Yttrium oxide (Y2O3), Titanium oxide (TiO2), Indium Gallium Zinc oxide (IGZO), Indium doped Zinc oxide (IZO), Tin oxide (SnO), and stabilized or partially stabilized zirconia.

### EXAMPLES

The disclosure is illustrated by the following non-limiting examples.

An portion of an OLED is constructed as in FIG. 2. The structure has a polymeric supporting substrate, five HRI substrate layers on the supporting substrate (having refractive indexes of 1.6, 1.7, 1.8, 1.9 and 2.0 respectively a transparent electrode residing on the fifth HRI substrate layer and an organic layer residing on the transparent electrode.

Various examples of producing HRI substrates are constructed as depicted in FIGS. 3-8B.

FIG. 3 shows production of a substrate with the gradation of refractive index, which is made by atomic layer deposition or slot die coating. As illustrated, a substrate (polymer film) may be provided. A first coating adhesive layer may be applied to the substrate. A nano-particle spray application may be applied to the first coating adhesive layer. As such, the nano-particles may adhere to the substrate. In certain aspects, the nanoparticles are configured to forma a mono layer. However, other configurations are possible. A second adhesive layer may be applied to the substrate stack, adjacent the deposited nano-particles. A nano-particle spray application may be applied to the second coating adhesive layer. As such, the nano-particles may adhere to the substrate stack forming a second nano-particle layer (e.g., mono layer). In certain aspects, the nanoparticles are configured to form a mono layer. In other aspects, multilayer nano-particles may be formed.

As an example, each layer may have thickness ranges from 5 nm to 100 nm. Refractive index can be controllable by varying thickness. Another example, each layer can have different nanoparticles which has refractive index.

FIG. 4 shows the production of a HRI substrate film using a screen printing method. As illustrated, a substrate (polymer film) may be disposed on a vacuum table. A screen comprising a frame and mesh portion may be disposed adjacent the substrate. A nano-particle solution may be applied to the mesh portion of the screen and a squeegee or load device may be used to apply a load to the screen to cause the nano-particle solution to move through the screen and to be applied to the substrate.

FIG. 5 shows production of a HRI substrate using an injection process. As illustrated, polymer and nano-particles may be mixed and delivered to a pelletizer. The output of the pelletizer may be fed to an input of an injection molding device, which may process the mixed pellets for molding. As an example, the nanoparticle compounding ratio ranges from 90 wt % to 5 wt % of the overall mixture.

The process described herein may be used to form HRI substrates. The HRI substrate may then be used in other applications such as OLED application. As an example, FIG. 6 shows the structure of transparent electrode on HRI substrate of which RI ranges from 1.7 to 2.0. As a further example, FIG. 7 shows production of a transparent electrode on a HRI substrate. Metal oxide such as ITO, SnO, IGZO, IZO can be deposited onto high heat resistant with high refractive index substrate. Or metal oxide such as liquid solution of ITO, SnO, IGZO, IZO can be coated and cured by an intense pulse light sintering method. In this case, ULTEM™ resin was used for base substrate. The illustrated process is a roll to roll process. As a further example, FIGS. 8A-B shows a schematic of a high refractive index substrate 850a-b integrated with transparent electrode layer 852a-b as two types. The transparent electrode materials can use the ITO, silver nanowire (Ag N/W), poly (3,4-ethylenedioxythiopene) PEDOT nanoparticles, Metal mesh (a nanofiber mesh with metal nanoparticles), ITO/transparent conducting oxides (TCO). FIG. 8A shows HRI particles 854a are placed on top of polymer film layer 851a and FIG. 8B shows HRI particles 854b are dispersed in whole substrate.

1. A high refractive index substrate suitable for inclusion in an organic light emitting diode (OLED), the high refractive index substrate comprising a polymeric material and nanoparticles dispersed therein, the size of the nanoparticles ranging from about 1 nm to about 50 nm.

2. The high refractive index substrate according to claim 1, wherein the high refractive index substrate is flexible and has a thickness in the range of from about 5 μm to about 250 μm.

3. The high refractive index substrate according to claim 1, wherein the nanoparticles up to 50 nm in size have a refractive index (n) of from about 1.7 to about 2.5.

4. The high refractive index substrate according to claim 1, having a transmittance from about 80% to about 95%.

5. The high refractive index substrate according to claim 1, having a water vapor transmission rate (WVTR) of 10−6 g/m2 day.

6. The high refractive index substrate according to claim 1, wherein the polymeric material comprises polycarbonate or polyetherimide.

7. The high refractive index substrate according to claim 1, wherein the nanoparticles comprise one or more of Zirconium oxide (ZrO2), Zinc oxide (ZnO), Aluminum oxide (Al2O3), Magnesium oxide (MgO), Calcium oxide (CaO), Aluminum nitride (AlN), Barium titanate (BaTiO3), Hafnium oxide (HfO2), Tantalum oxide (Ta2O5), Cerium oxide (CeO2), Yttrium oxide (Y2O3), Titanium oxide (TiO2), Indium Gallium Zinc oxide (IGZO), Indium doped Zinc oxide (IZO), Tin oxide (SnO), and stabilized or partially stabilized zirconia.

8. The high refractive index substrate according to claim 1, wherein the high refractive index substrate including the nanoparticles dispersed therein exhibits improved storage modulus and reduced efficiency of thermal expansion as compared to a substantially similar substrate without the nanoparticles.

9. The high refractive index substrate according to claim 1, wherein the high refractive index substrate has no photocatalytic reactivity in ultraviolet wavelength range.

10. The high refractive index substrate according to claim 1, where the high refractive index substrate has a yellow index value below 2.

11. The high refractive index substrate according to claim 1, further comprising a transparent electrode layer.

12. The high refractive index substrate according to claim 1, wherein a gradation of refractive index is achieved by coating an adhesive onto the high refractive index substrate and by spraying the nanoparticles onto the adhesive.

13. The high refractive index substrate according to claim 1, further comprising nanoparticles having a size greater than 100 nm.

14. The high refractive index substrate according to claim 13, wherein the nanoparticles having a size greater than 100 nm are formed by an adhesive transfer method, a coating method or a deposition method.

15. An OLED comprising:
a high refractive index substrate according to claim 1;
an anode layer disposed adjacent to the high refractive index substrate;
a phosphor layer disposed on the anode layer; and
a cathode layer disposed on the phosphor layer.

16. The OLED according to claim 15, wherein the high refractive index substrate is flexible and has a thickness in the range of from about 5 μm to about 250 μm.

17. The OLED according to claim 15, wherein the high refractive index substrate having a refractive index (n) of from about 1.7 to about 2.5.

18. The OLED according to claim 15, wherein the high refractive index substrate has a transmittance from about 80% to about 95%.

19. The OLED according to claim 15, wherein the high refractive index substrate has a water vapor transmission rate (WVTR) with 10−6 g/m2 day.

20. The OLED according to claim 15, wherein the high refractive index substrate comprises nanoparticles dispersed throughout, wherein the nanoparticles comprise one or more of Zirconium oxide (ZrO2), Zinc oxide (ZnO), Aluminum oxide (Al2O3), Magnesium oxide (MgO), Calcium oxide (CaO), Aluminum nitride (AIN), Barium titanate (BaTiO3), Hafnium oxide (HfO2), Tantalum oxide (Ta2O5), Cerium oxide (CeO2), Yttrium oxide (Y2O3), Titanium oxide (TiO2), Indium Gallium Zinc oxide (IGZO), Indium doped Zinc oxide (IZO), Tin oxide (SnO), and stabilized or partially stabilized zirconia.
